(19) United States
(12) Patent Application Publication
(10) Pub. No.: US 2017/0141124 A1
(43) Pub. Date: May 18, 2017

(54) SEMICONDUCTOR MEMORY DEVICE AND METHOD FOR MANUFACTURING SAME

(71) Applicant: KABUSHIKI KAISHA TOSHIBA, Minato-ku (JP)

(72) Inventor: Hironobu HAMANAKA, Yokkaichi (JP)

(73) Assignee: KABUSHIKI KAISHA TOSHIBA, Minato-ku (JP)

(21) Appl. No.: 15/056,066

(22) Filed: Feb. 29, 2016

Related U.S. Application Data
(60) Provisional application No. 62/256,425, filed on Nov. 17, 2015.

(51) Int. Cl. H01L 27/115; H01L 29/06

(52) U.S. Cl. CPC H01L 27/11582; H01L 27/11565; H01L 29/0649

(57) ABSTRACT

According to one embodiment, a semiconductor memory device includes a substrate; a stacked body including a plurality of electrode layers stacked with an insulating layer interposed; a first semiconductor film; a first insulating film including a charge storage film; and a second semiconductor film. The first semiconductor film includes a first semiconductor portion and a second semiconductor portion. The first insulating film includes a first insulating unit having a lower surface contacting the second semiconductor portion, and a second insulating unit. The second semiconductor film includes a third semiconductor portion having a lower surface lower than a height of the lower surface of the first insulating unit, and a fourth semiconductor portion.

### CROSS-REFERENCE TO RELATED APPLICATIONS

This application is based upon and claims the benefit of priority from U.S. Provisional Patent Application 62/256,425 field on Nov. 17, 2015; the entire contents of which are incorporated herein by reference.

### FIELD

Embodiments described herein relate generally to a semiconductor memory device and a method for manufacturing same.

### BACKGROUND

A semiconductor memory device having a three-dimensional structure has been proposed in which multiple memory cells stacked with an insulating layer interposed are provided.

The supply of a stable cell current is one challenge for such a memory device.

### BRIEF DESCRIPTION OF THE DRAWINGS

FIG. 1 is a schematic perspective view of a memory cell array of a first embodiment;

FIG. 2 is a schematic cross-sectional view of the semiconductor memory device of the first embodiment;

FIG. 3A is an enlarged schematic cross-sectional view of a columnar portion of the first embodiment, and FIG. 3B is a schematic cross-sectional view of the semiconductor memory device of the first embodiment;

FIG. 4A to FIG. 8B are schematic cross-sectional views showing a method for manufacturing the semiconductor memory device of the first embodiment;

FIG. 9A and FIG. 9B are schematic cross-sectional views of the semiconductor memory device of a second embodiment; and

FIG. 10A to FIG. 11B are schematic cross-sectional views showing a method for manufacturing the semiconductor memory device of the second embodiment.

### DETAILED DESCRIPTION

According to one embodiment, a semiconductor memory device includes a substrate; a stacked body provided on the substrate, the stacked body including a plurality of electrode layers stacked with an insulating layer interposed; a first semiconductor film provided as one body inside the stacked body and inside the substrate; a first insulating film provided inside the stacked body and inside the substrate, the first insulating film including a charge storage film; and a second semiconductor film provided inside the stacked body and inside the substrate. The first semiconductor film includes a first semiconductor portion provided inside the stacked body, the first semiconductor portion extending in a stacking direction of the stacked body, and a second semiconductor portion provided inside the substrate and being in contact with the substrate. The first insulating film includes a first insulating unit provided between the first semiconductor portion and the plurality of electrode layers, the first insulating unit extending in the stacking direction and having a lower surface contacting the second semiconductor portion, and a second insulating unit provided inside the substrate, the second insulating unit being separated from the first insulating unit with the second semiconductor portion interposed, the second insulating unit contacting the substrate and the second semiconductor portion. The second semiconductor film includes a third semiconductor portion provided between the first semiconductor portion and the first insulating unit, the third semiconductor portion extending in the stacking direction and having a lower surface lower than a height of the lower surface of the first insulating unit, and a fourth semiconductor portion provided inside the substrate, separated from the third semiconductor portion and the substrate, and provided between the second semiconductor portion and the second insulating unit.

Embodiments are described below with reference to the drawings. Note that in the drawings, the same components are denoted by the same reference numerals and signs.

### First Embodiment

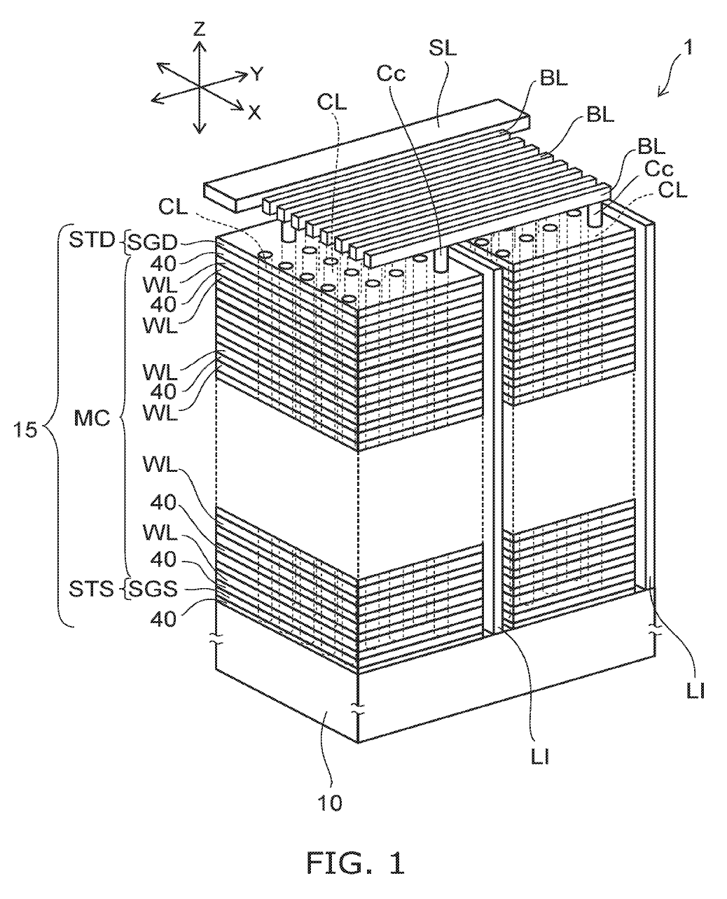

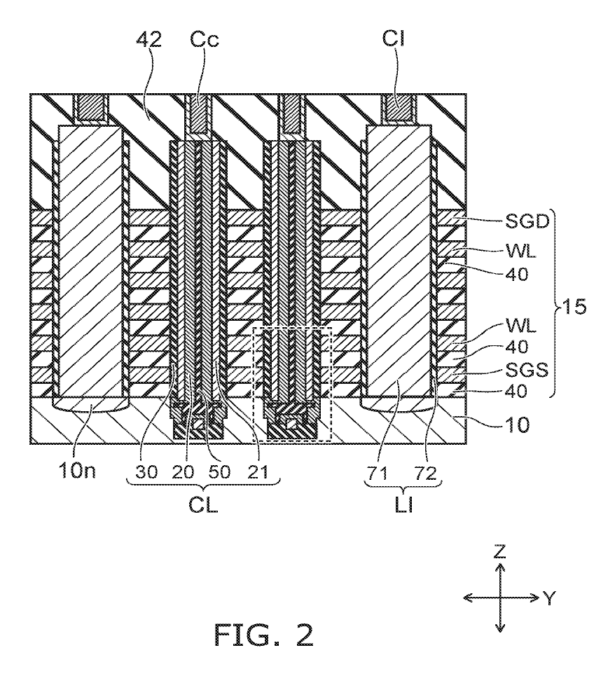

An example of the configuration of a memory cell array 1 of the embodiment will now be described with reference to FIG. 1 and FIG. 2.

FIG. 1 is a schematic perspective view of the memory cell array 1 of the embodiment. In FIG. 1, the insulating layers, etc., that are on the stacked body are not shown for easier viewing of the drawing.

In FIG. 1, two mutually-orthogonal directions parallel to a major surface of a substrate 10 are taken as an X-direction and a Y-direction; and a direction orthogonal to both the X-direction and the Y-direction is taken as a Z-direction (a stacking direction).

FIG. 2 is a schematic cross-sectional view of the semiconductor memory device of the embodiment. The upper layer interconnects are not shown in FIG. 2.

As shown in FIG. 1 and FIG. 2, the memory cell array 1 includes a stacked body 15, multiple columnar portions CL, an interconnect layer LI, and upper layer interconnects. Bit lines BL and a source layer SL are shown as the upper layer interconnects in FIG. 1.

The stacked body 15 is provided on the substrate 10. The stacked body 15 includes multiple electrode layers WL, multiple insulating layers 40, a source-side selection gate SGS, and a drain-side selection gate SGD.

The multiple electrode layers WL are stacked with the multiple insulating layers 40 interposed. The multiple insulating layers 40 include, for example, an air gap (a gap). The number of stacks of the electrode layers WL shown in the drawing is an example; and the number of stacks of the electrode layers WL is arbitrary.

The source-side selection gate SGS is provided on the substrate 10 with the insulating layer 40 interposed. The drain-side selection gate SGD is provided in the uppermost layer of the stacked body 15. The multiple electrode layers WL are provided between the source-side selection gate SGS and the drain-side selection gate SGD.

The electrode layers WL include a metal. The electrode layers WL include, for example, at least one of tungsten, molybdenum, titanium nitride, or tungsten nitride and may include silicon or a metal silicide. The source-side selection gate SGS and the drain-side selection gate SGD include the same material as the electrode layers WL.

Although the thickness of one layer of the drain-side selection gate SGD and the source-side selection gate SGS normally is thicker than the thickness of one layer of the electrode layers WL, the thickness of one layer of the drain-side selection gate SGD and the source-side selection gate SGS may be about the same as or thinner than the thickness of one layer of the electrode layers WL. Each of the selection gates (SGD and SGS) may be provided not as one layer but as multiple layers. Here, “thickness” refers to the thickness in the stacking direction of the stacked body 15 (the Z-direction).

The multiple columnar portions CL that extend in the Z-direction are provided inside the stacked body 15. For example, the columnar portions CL are provided in circular columnar or elliptical columnar configurations. For example, the multiple columnar portions CL are provided in a staggered lattice configuration. Or, the multiple columnar portions CL may be provided in a square lattice configuration along the X-direction and the Y-direction. The columnar portions CL are electrically connected to the substrate 10.

The structures of the columnar portion CL and the interconnect layer LI will now be described using the schematic cross-sectional view of FIG. 2. As shown in FIG. 2, the columnar portion CL includes a channel body 20 (a first semiconductor film), a cover film 21 (a second semiconductor film), a memory film 30 (a first insulating film), and a core insulating film 50 (a second insulating film). The memory film 30 is provided between the electrode layer WL and the channel body 20; and the cover film 21 is provided between the channel body 20 and the memory film 30. For example, a not-shown oxide film may be provided between the channel body 20 and the cover film 21.

The memory film 30 surrounds the cover film 21, the channel body 20, and the core insulating film 50. The memory film 30, the cover film 21, the channel body 20, and the core insulating film 50 extend in the Z-direction. The core insulating film 50 is provided on the inner side of the channel body 20.

The channel body 20 and the cover film 21 are, for example, silicon films having silicon as major components and include, for example, polysilicon. The core insulating film 50 includes, for example, a silicon oxide film and may include an air gap.

As shown in FIG. 1, the interconnect layer LI that extends in the X-direction and the Z-direction is provided inside the stacked body 15 and divides the adjacent stacked bodies 15. Further, the interconnect layer LI multiply extends similarly in the Y-direction as well (not shown for the Y-direction) at the periphery of the memory cell array 1. That is, when the memory cell array 1 is viewed from above, the interconnect layer LI has a structure provided in a matrix configuration. Therefore, the stacked body 15 has a structure of being divided into a matrix configuration by the interconnect layer LI.

As shown in FIG. 2, the interconnect layer LI includes a conductive film 71 and an insulating film 72. The insulating film 72 is provided on the side wall of the interconnect layer LI. The conductive film 71 is provided on the inner side of the insulating film 72.

The lower end of the interconnect layer LI contacts a semiconductor portion 10n of the substrate 10. The interconnect layer LI may be electrically connected, via the substrate 10, to the channel body 20 inside the columnar portion CL. The upper end of the interconnect layer LI is electrically connected to the source layer SL via a contact unit CI.

The multiple bit lines BL (e.g., the metal films) are provided on the stacked body 15. The multiple bit lines BL are separated from each other in the X-direction and extend in the Y-direction. Each of the bit lines BL is connected to one of the multiple channel bodies 20 selected from each of the regions separated with the interconnect layer LI interposed in the Y-direction.

The upper end of the channel body 20 is electrically connected to the bit line BL via a contact unit Cc. The lower end of the channel body 20 contacts the substrate 10.

A drain-side selection transistor STD is provided at the upper end portion of the columnar portion CL; and a source-side selection transistor STS is provided at the lower end portion of the columnar portion CL.

Memory cells MC, the drain-side selection transistor STD, and the source-side selection transistor STS are vertical transistors that can cause a current to flow in the stacking direction of the stacked body 15 (the Z-direction).

The selection gates SGD and SGS function respectively as gate electrodes (control gates) of the selection transistors STD and STS. An insulating film (the memory film 30) that functions as the gate insulator films of the selection transistors STD and STS is provided between the channel body 20 and the selection gates SGD and SGS.

The multiple memory cells MC in which the electrode layers WL of each layer are control gates are provided between the drain-side selection transistor STD and the source-side selection transistor STS.

The multiple memory cells MC, the drain-side selection transistor STD, and the source-side selection transistor STS are connected in series by the channel body 20 and are included in one memory string. The multiple memory cells MC are provided three-dimensionally in the X-direction, the Y-direction, and the Z-direction by providing the memory strings in, for example, a staggered lattice configuration in a planar direction parallel to the X-Y plane.

The semiconductor memory device of the embodiment can freely and electrically erase/program data and can retain the memory content even when the power supply is OFF.

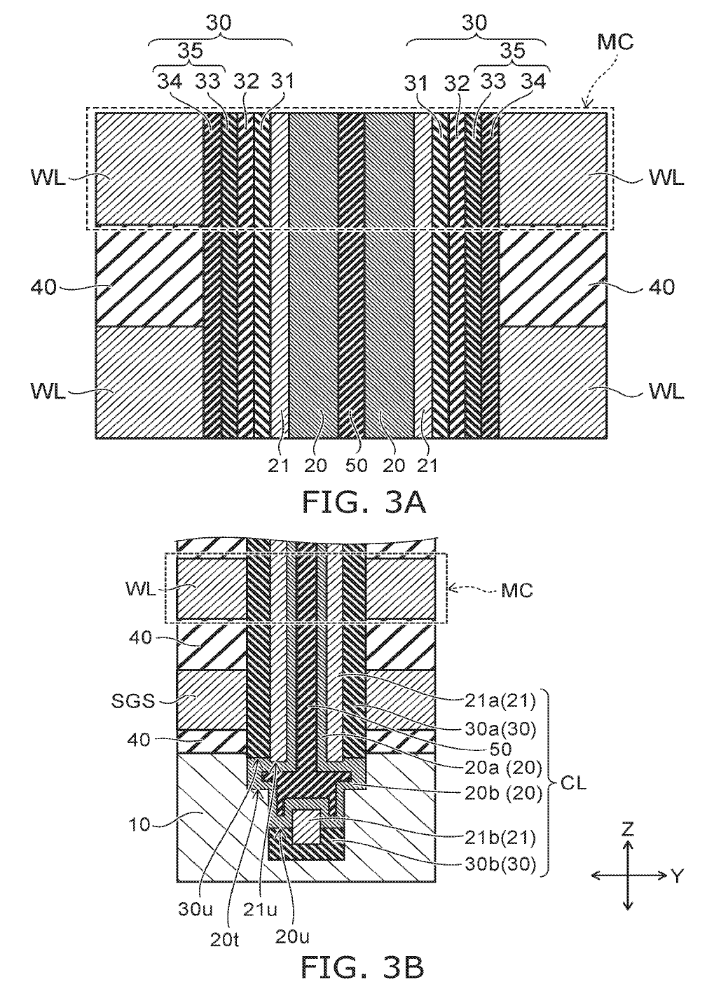

An example of the memory cell MC of the embodiment will now be described with reference to FIG. 3A.

FIG. 3A is an enlarged schematic cross-sectional view of a portion of the columnar portion CL of the embodiment.

The memory cell MC is, for example, a charge trap memory cell and includes the electrode layer WL, the memory film 30, the cover film 21, the channel body 20, and the core insulating film 50.

The memory film 30 includes a charge storage film 32, a tunneling insulating film 31, and a blocking insulating film 35. The tunneling insulating film 31 is provided in contact with the cover film 21. The charge storage film 32 is provided between the blocking insulating film 35 and the tunneling insulating film 31.

The channel body 20 functions as a channel of the memory cell MC; and the electrode layer WL functions as a control gate of the memory cell MC. The charge storage film 32 functions as a data storage layer and stores charge injected from the channel body 20. The blocking insulating film 35 prevents the charge stored in the charge storage film 32 from diffusing into the electrode layer WL. In other words, the memory cells MC that have structures in which the control gate surrounds the periphery of the channel are formed at the intersections between the channel body 20 and each of the electrode layers WL.

The blocking insulating film 35 includes, for example, a capping film 34 and a blocking film 33. The blocking film 33 is provided between the capping film 34 and the charge storage film 32. The blocking film 33 is, for example, a silicon oxide film.

The capping film 34 is provided in contact with the electrode layer WL. The capping film 34 includes a film having a dielectric constant that is higher than that of the blocking film 33.

By providing the capping film 34 in contact with the electrode layer WL, back-tunneling electrons injected from the electrode layer WL when erasing can be suppressed; and the charge blocking properties can be increased.

The charge storage film 32 has many trap sites that trap charge. The charge storage film 32 includes, for example, at least one of silicon nitride film or hafnium oxide.

The tunneling insulating film 31 is used as a potential barrier when the charge is injected from the channel body 20 into the charge storage film 32 or when the charge stored in the charge storage film 32 diffuses into the channel body 20. The tunneling insulating film 31 includes, for example, a silicon oxide film.

Or, a stacked film (an ONO film) that has a structure in which a silicon nitride film is interposed between a pair of silicon oxide films may be used as the tunneling insulating film 31. In the case where the ONO film is used as the tunneling insulating film 31, compared to a single-layer of the silicon oxide film, the erasing operation is performed using a low electric field.

An example of the configuration of the semiconductor memory device of the embodiment will now be described with reference to FIG. 3B.

FIG. 3B is a schematic cross-sectional view of the dotted line portion shown in FIG. 2.

As shown in FIG. 3B, the channel body 20 includes a first semiconductor portion 20a and a second semiconductor portion 20b provided as one body. The first semiconductor portion 20a extends in the Z-direction and is provided inside the stacked body 15.

The second semiconductor portion 20b is provided inside the substrate 10 and contacts the substrate 10. The second semiconductor portion 20b includes a stepped portion 20t and a lower surface 20u, the stepped portion 20t contacts the substrate 10, and the lower surface 20u contacts the memory film 30. By providing the stepped portion 20t inside the substrate 10, the fluctuation when removing a portion of the memory film 30 described below can be suppressed. Also, the surface area where the channel body 20 contacts the substrate 10 can be increased; and it is possible to increase the cell current.

As shown in the manufacturing method described below, for example, polysilicon that is formed by heating (crystallization annealing of) amorphous silicon is used as the channel body 20. At this time, the second semiconductor portion 20b that is provided to be proximal to the substrate 10 is crystallized by inheriting the crystal structure of the substrate 10. On the other hand, the first semiconductor portion 20a that is separated from the substrate 10 is crystallized by, for example, inheriting the crystal structure of the cover film 21.

In other words, the crystal structure that is formed when performing crystallization annealing of the amorphous silicon is different between the locations where the amorphous silicon is provided. Here, because the substrate 10 is monocrystalline, the likelihood is high that the amorphous silicon proximal to the substrate 10 will be monocrystallized, or polycrystallized to be substantially monocrystalline. On the other hand, for the amorphous silicon separated from the substrate 10, the likelihood of being monocrystallized is low; and the likelihood of being polycrystallized (polysilicon) is high.

Therefore, the second semiconductor portion 20b has a crystal structure (a second crystal structure) that is substantially equal to the crystal structure of the substrate 10 (here, monocrystalline). On the other hand, the first semiconductor portion 20a has a crystal structure (a first crystal structure) that is different from the crystal structure of the substrate 10. These crystal structures are elaborated in the description of the manufacturing method described below. The “second crystal structure” is one of a monocrystalline crystal structure or a crystal structure having monocrystalline as a major structure; and the “first crystal structure” is one of a polycrystalline crystal structure or a crystal structure having polycrystalline as a major structure.

The memory film 30 includes a first insulating unit 30a and a second insulating unit 30b that are provided to be separated from each other. The first insulating unit 30a is provided between the first semiconductor portion 20a and the multiple electrode layers WL, and the first insulating unit 30a extends in the Z-direction. The first insulating unit 30a has a lower surface 30u that contacts the second semiconductor portion 20b. The lower surface 30u is provided at a height not higher than the height of the surface of the substrate 10 contacting the stacked body 15. The distance between the lower surface 30u and the height of the surface of the substrate 10 contacting the stacked body 15 is, for example, 10 nm or less. Here, “height” refers to the height in the Z-direction with reference to the surface of the substrate 10 contacting the stacked body 15, and refers to the position being higher from the substrate 10 toward the stacked body 15.

The second insulating unit 30b is provided inside the substrate 10. The second insulating unit 30b contacts the substrate 10 and the lower surface 20u of the second semiconductor portion 20b. The first insulating unit 30a is separated from the second insulating unit 30b with the second semiconductor portion 20b interposed.

The stepped portion 20t of the second semiconductor portion 20b is provided at a height between the height of the lower surface 30u of the first insulating unit 30a and the height of the lower surface 20u of the second semiconductor portion 20b. Also, when viewed from the Z-direction, the stepped portion 20t and the lower surface 30u of the first insulating unit 30a overlap.

For example, the side surface of the first insulating unit 30a is coplanar with the side surface of the second semiconductor portion 20b higher than the stepped portion 20t. For example, the side surface of the second insulating unit 30b is coplanar with the side surface of the second semiconductor portion 20b at or lower than the stepped portion 20t.

The cover film 21 includes a third semiconductor portion 21a and a fourth semiconductor portion 21b that are provided to be separated from each other. The third semiconductor portion 21a is provided between the first semiconductor portion 20a and the first insulating unit 30a and extends in the Z-direction.

The third semiconductor portion 21a has a lower surface 21u that contacts the second semiconductor portion 20b. The lower surface 21u of the third semiconductor portion 21a is provided at a height between the height of the lower surface 30u of the first insulating unit 30a and the height of the stepped portion 20t. Also, the lower surface 30u of the first insulating unit 30a is provided at a height between the height of the surface of the substrate 10 contacting the stacked body 15 and the height of the lower surface 21u of the third semiconductor portion 21a. By such a configuration, it is possible to form the channel body 20 at a position proximal to the surface of the substrate 10 contacting the stacked body 15 in the manufacturing process described below; and an improvement of the cell current can be realized.

The fourth semiconductor portion 21b is provided inside the substrate 10 and is provided between the second semiconductor portion 20b and the second insulating unit 30b. The fourth semiconductor portion 21b is separated, with the second semiconductor portion 20b interposed, from the third semiconductor portion 21a and the substrate 10. The side surface of the fourth semiconductor portion 21b is surrounded with the second insulating unit 30b and the second semiconductor portion 20b.

The core insulating film 50 is provided as one body on the inner side of the channel body 20. The core insulating film 50 is separated from the cover film 21 with the channel body 20 interposed.

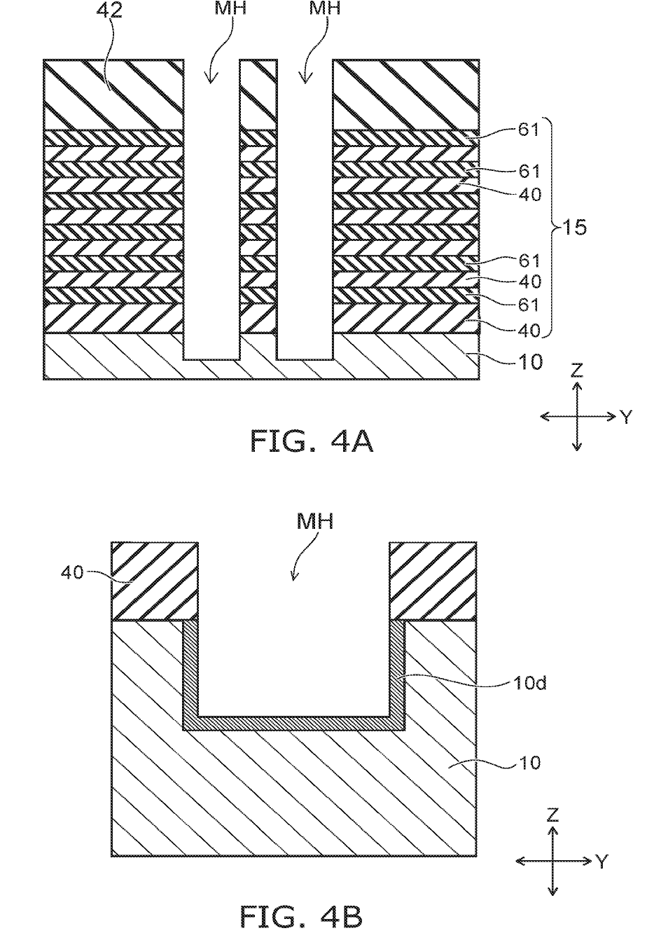

An example of a method for manufacturing the semiconductor memory device of the embodiment will now be described with reference to FIG. 4A to FIG. 8B.

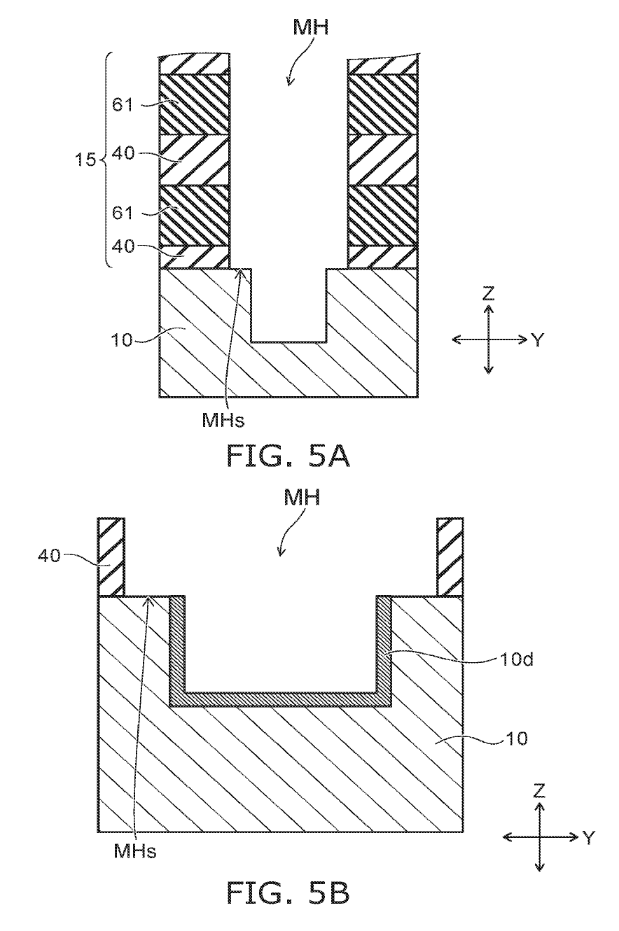

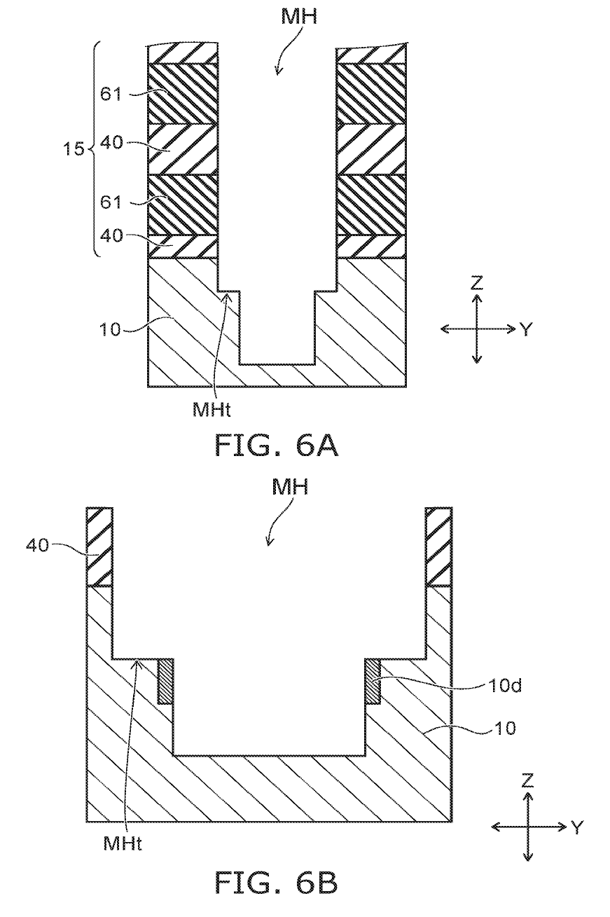

FIG. 4B, FIG. 5B, and FIG. 6B respectively are enlarged schematic cross-sectional views of portions of FIG. 4A, FIG. 5A, and FIG. 6A.

First, after forming an element separation region on the substrate 10, peripheral transistors (not shown) are formed.

Then, as shown in FIG. 4A, the insulating layers 40 are formed on the substrate 10. Multiple sacrificial layers 61 (multiple first layers) are stacked with multiple insulating layers 40 interposed on the insulating layer 40. Thereby, the stacked body 15 is formed. An insulating layer 42 is formed on the stacked body 15.

The sacrificial layer 61 includes, for example, a silicon nitride film. The insulating layer 40 includes, for example, a silicon oxide film.

Subsequently, a hole MH that pierces the insulating layer 42 and the stacked body 15 and reaches the interior of the substrate 10 is made. For example, RIE (Reactive Ion Etching) using a not-shown mask is used as the method for making the hole MH. The substrate 10 and the side surface of the stacked body 15 (the side surfaces of the multiple sacrificial layers 61 and the side surfaces of the multiple insulating layers 40) are exposed at the side surface of the hole MH. The substrate 10 is exposed at the bottom surface of the hole MH.

For example, a fluorocarbon-based gas is used in the RIE when making the hole MH. At this time, as shown in FIG. 4B, a damaged portion 10d is formed at the surface vicinity of the substrate 10 exposed in the hole MH. The damaged portion 10d is a portion that has degraded due to effects of the fluorocarbon and is, for example, the state in which an impurity is included inside the substrate 10.

Then, as shown in FIG. 5A, the side surface of the stacked body 15 exposed at the side surface of the hole MH is caused to recede (post clean). Thereby, a stepped portion MHs is formed in the surface of the substrate 10 contacting the stacked body 15.

When viewed from the Z-direction, the maximum diameter of the hole MH higher than the stepped portion MHs is larger than the maximum diameter of the hole MH lower than the stepped portion MHs. At this time, as shown in FIG. 5B, the stepped portion MHs is formed on the damaged portion 10d formed in the side surface of the substrate 10.

Subsequently, as shown in FIG. 6A, the stepped portion MHs and the hole MH bottom surface are caused to recede. Thereby, a stepped portion MHt is formed at a height that is lower than the height of the surface of the substrate 10 contacting the stacked body 15.

At this time, the removal amount of the substrate 10 is low compared to the removal amount of the stacked body 15 and the substrate 10 when making the hole MH described above. Therefore, the fluctuation in the depth direction of the stepped portion MHt caused to recede is smaller than the fluctuation in the depth direction of the initial formation of the hole MH bottom portion. Thereby, when forming the channel body 20 described below inside the hole MH, the fluctuation of the portion contacting the side surface of the substrate 10 can be suppressed; and the supply of a stable cell current is possible.

Also, RIE using, for example, Cl₂ gas is used as the method for causing the stepped portion MHt and the hole MH bottom surface to recede. In the case where Cl₂ gas is used, compared to the case where the fluorocarbon-based gas described above is used, the degradation of the surface of the substrate 10 can be suppressed. Therefore, the damaged portion 10d is not formed newly at the surface vicinity of the substrate 10 when causing the stepped portion MHt and the hole MH bottom surface to recede.

Further, as shown in FIG. 6B, by causing the stepped portion MHt and the hole MH bottom surface to recede by the RIE using the Cl₂ gas described above, a portion of the damaged portion 10d formed when making the hole MH can be removed.

In particular, the damaged portion 10d proximal to the surface of the substrate 10 contacting the stacked body 15 can be removed. Thereby, the occurrence of traps of electrons caused by the damaged portion 10d can be suppressed. Therefore, the electrical resistance on the substrate 10 surface can be suppressed; and an improvement of the cell current is realized.

Although the damaged portion 10d remains under the stepped portion MHt, because this is a region that is distal to the substrate 10 upper surface, the effects of the remaining damaged portion 10d on the cell current are slight.

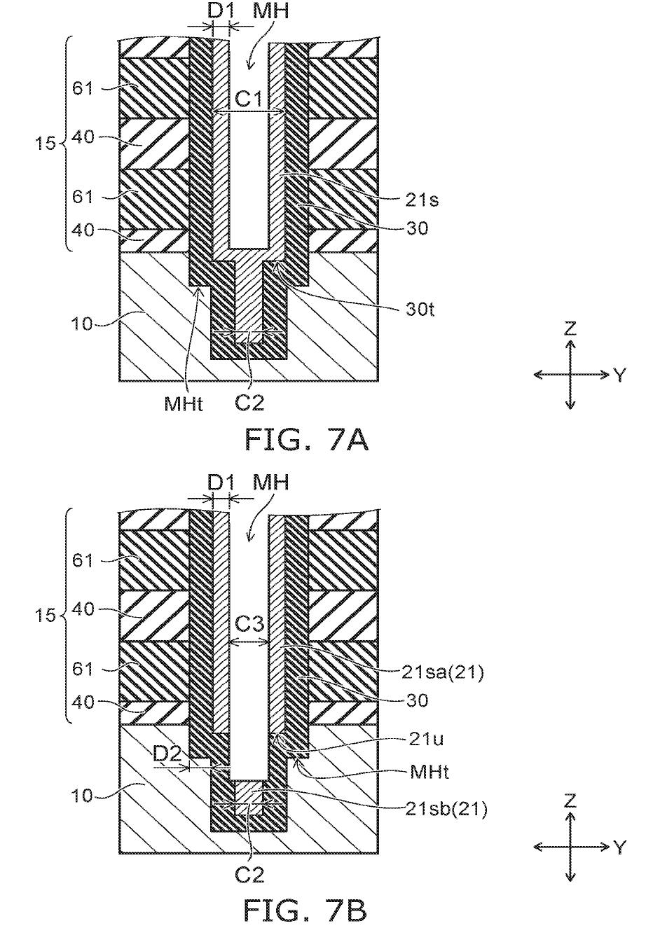

As shown in FIG. 7A, the memory film 30 that includes the charge storage film 32 shown in FIG. 3A is formed on the side walls (the side surface and bottom surface) of the hole MH. The memory film 30 is formed conformally inside the hole MH.

The maximum diameter of the memory film 30 higher than the stepped portion MHt is larger than the maximum diameter of the memory film 30 at or lower than the stepped portion MHt. A stepped portion 30t of the memory film 30 is formed between the height of the stepped portion MHt and the height of the surface of the substrate 10 contacting the stacked body 15. In the case where the height of the stepped portion 30t is not less than the height of the surface of the substrate 10 contacting the stacked body 15, the likelihood becomes high that the memory film 30 may be removed up to the memory film 30 inside the stacked body 15 in the process of removing the memory film 30 described below; and the device characteristics degrade. Therefore, it is desirable for the height of the stepped portion 30t to be a height lower than the stacked body 15.

Then, a cover film 21s is formed on the inner side of the memory film 30. The cover film 21s is, for example, a silicon-based amorphous film such as amorphous silicon, etc.

When viewed from the Z-direction, a maximum diameter C1 of the cover film 21s formed to be higher than the stepped portion 30t is larger than a maximum diameter C2 of the cover film 21s formed to be at or lower than the stepped portion 30t. Also, a thickness D1 in the Y-direction (a first direction) of the cover film 21s formed inside the stacked body 15 is not less than the value of the maximum diameter C2 divided by 2. Thereby, the cover film 21s is filled onto the inner side of the memory film 30 at or lower than the stepped portion 30t. At this time, the height of the bottom surface of the space inside the hole MH not filled with the cover film 21s is higher than the height of the stepped portion 30t.

Subsequently, as shown in FIG. 7B, the cover film 21s that is formed on the bottom surface of the space inside the hole MH is caused to recede. At this time, the side surface of the memory film 30 is exposed in the space inside the hole MH. For example, RIE using a not-shown mask is used as the method for causing the cover film 21s to recede.

Thereby, a third semiconductor portion 21sa and a fourth semiconductor portion 21sb are formed by dividing the cover film 21s vertically. The lower surface 21u of the third semiconductor portion 21sa is formed at the portion contacting the stepped portion 30t of the memory film 30.

When viewed from the Z-direction, a maximum inner diameter C3 of the third semiconductor portion 21sa is not less than the maximum diameter C2 of the fourth semiconductor portion 21sb. Also, a width D2 of the stepped portion MHt in the Y-direction is not less than the thickness D1 of the third semiconductor portion 21sa. At this time, the side surface of the memory film 30 can be exposed at the side surface of the space inside the hole MH by causing the cover film 21s to recede in the Z-direction. The side surface of the memory film 30 is exposed in the space inside the hole MH between the third semiconductor portion 21sa and the fourth semiconductor portion 21sb.

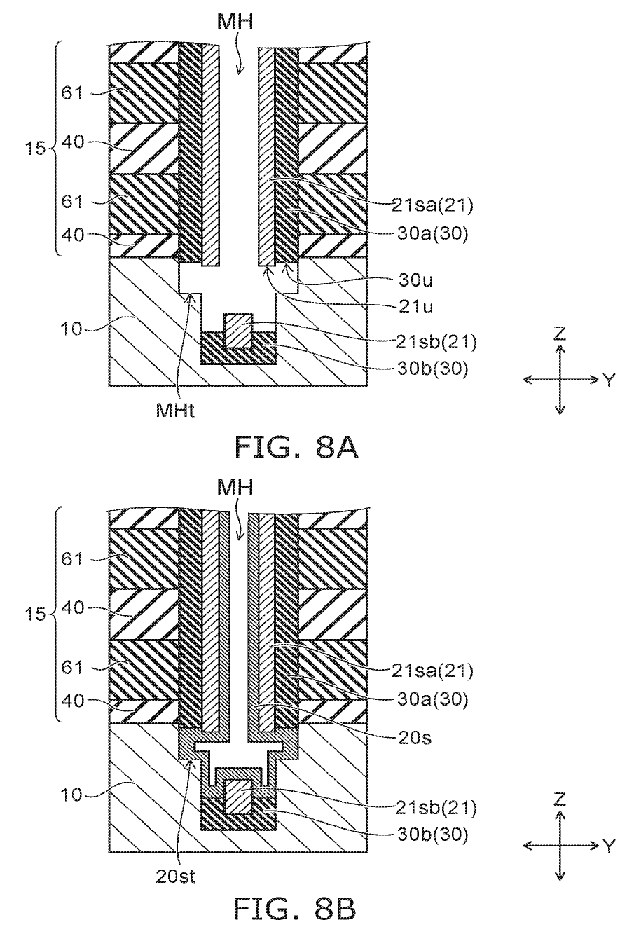

Subsequently, as shown in FIG. 8A, the memory film 30 is removed via the space inside the hole MH. The memory film is removed until the side surface of the substrate 10 including the stepped portion MHt is exposed in the space inside the hole MH. At this time, the first insulating unit 30a and the second insulating unit 30b are formed by dividing the memory film 30 vertically.

The lower surface 30u of the first insulating unit 30a is formed at a height between the height of the surface of the substrate 10 contacting the stacked body 15 and the height of the lower surface 21u of the third semiconductor portion 21sa. The lower surface 21u of the third semiconductor portion 21sa is formed at a height between the height of the lower surface 30u of the first insulating unit 30a and the height of the stepped portion MHt. Thereby, when forming the channel body 20 described below, the supply of a stable cell current is possible.

For example, when causing the cover film 21s described above to recede, there are cases where the side surface of the memory film 30 is not exposed in the space inside the hole MH; and only the lower end portion of the memory film 30 is exposed. In such a case, because the substrate 10 side surface is exposed in the space inside the hole MH, the memory film 30 is removed from the lower end portion of the memory film 30 to the lower surface vicinity of the stacked body 15. At this time, because the removal is performed from the lower end portion of the memory film 30 toward a high position, the removal amount of the memory film 30 is higher compared to when the removal is performed from the side surface of the memory film 30. As the removal amount of the memory film 30 becomes high, the fluctuation of the position in the Z-direction where the lower surface 30u of the memory film 30 is formed becomes large.

In the case where the fluctuation of the position where the lower surface 30u of the memory film 30 is formed becomes large, for example, the likelihood becomes high that the lower surface 30u may be formed at a position that is excessively lower than the surface of the substrate 10 contacting the stacked body 15. In such a case, the distance between the upper surface of the substrate 10 and the channel body 20 that is subsequently formed lengthens; and a parasitic resistance occurs easily inside the substrate 10 between the channel body 20 and the upper surface of the substrate 10. Thereby, there is a possibility that the cell current may be reduced. In other words, the fluctuation of the cell current becomes large because the likelihood becomes high that the fluctuation of the distance from the upper surface of the substrate 10 to the surface contacting the channel body 20 may become large as the fluctuation of the position of the lower surface 30u becomes large.

In addition to the description recited above, for example, the likelihood becomes high that the lower surface 30u may be formed inside the stacked body 15 in the case where the fluctuation of the position where the lower surface 30u of the memory film 30 is formed becomes large. In such a case, there is a possibility that the channel body 20 that is formed subsequently may be shorted to the electrode layer WL or the source-side selection gate SGS. In other words, as the fluctuation of the position of the lower surface 30u of the memory film 30 becomes large, the likelihood becomes high that the channel body 20 may be shorted inside the stacked body 15; and there is a possibility that the characteristics of the device may degrade.

On the other hand, according to the embodiment, the removal is performed from the side surface of the memory film 30 mainly in the thickness direction (the XY-direction). At this time, the removal amount of the memory film 30 can be lower than in the case where the memory film 30 is removed from the lower end portion. Therefore, the fluctuation of the position where the lower surface 30u of the memory film 30 is formed can be suppressed. Thereby, when the channel body 20 is formed in the portion where the memory film 30 is removed, the fluctuation of the surface area of the surface of the channel body 20 contacting the substrate 10, the distance from the channel body 20 to the surface of the substrate 10 contacting the stacked body 15, etc., can be suppressed. In other words, the fluctuation of the cell current can be suppressed; and the supply of a stable cell current is possible.

When the side surface of the memory film 30 is removed by the process described above, the second insulating unit 30b and the fourth semiconductor portion 21sb are exposed in the space inside the hole MH. The fourth semiconductor portion 21sb contacts the second insulating unit 30b and is surrounded with the second insulating unit 30b. At this time, the fourth semiconductor portion 21sb is fixed by the second insulating unit 30b; and the fourth semiconductor portion 21sb that becomes dust can be suppressed.

For example, in the case where the second insulating unit 30b is not formed at the periphery of the fourth semiconductor portion 21sb, the fourth semiconductor portion 21sb is not fixed inside the hole MH and becomes dust; and there is a possibility that defects of the device may be caused.

Conversely, according to the embodiment, the fourth semiconductor portion 21sb is fixed inside the hole MH. Thereby, the fourth semiconductor portion 21sb that becomes dust can be suppressed; and it is possible to increase the yield of the device.

For example, isotropic etching using conditions having a high selectivity with respect to silicon is used as the method for removing the memory film 30 shown in FIG. 8A. As the isotropic etching, for example, a method (e.g., the Siconi Process™, etc.) may be used in which one cycle of etching of an etchant reaction and heating at a low temperature (e.g., about 200° C.) is multiply implemented. For example, gas types of ammonia (NH₃) and nitrogen trifluoride (NF₃) are used in the etching. Other than the description recited above, for example, wet etching using hot phosphoric acid, etc., may be used.

Then, as shown in FIG. 8B, a channel body 20s is formed as one body inside the hole MH. The channel body 20s includes a stepped portion 20st that contacts the substrate 10. The channel body 20s is, for example, a silicon-based amorphous film of amorphous silicon, etc.

The channel body 20s contacts the lower surface 30u of the first insulating unit 30a and the side surface and lower surface 20u of the third semiconductor portion 21sa at a position that is higher than the stepped portion 20st. The channel body 20s contacts the upper surface of the second insulating unit 30b and the side surface and upper surface of the fourth semiconductor portion 21sb at a position that is lower than the stepped portion 20st.

Subsequently, as shown in FIG. 3B, heating (crystallization annealing) of the channel body 20s and the cover film 21s is performed. Thereby, the channel body 20 and the cover film 21 that are crystallized are formed. At this time, the first semiconductor portion 20a that is formed inside the stacked body 15 and the second semiconductor portion 20b that is formed inside the substrate 10 are formed in the channel body 20. The first semiconductor portion 20a and the second semiconductor portion 20b are formed as one body. For example, the first semiconductor portion 20a has the crystal structure (the first crystal structure) that is different from the crystal structure (the second crystal structure) of the second semiconductor portion 20b.

A portion of the second semiconductor portion 20b included in the channel body 20 is formed in contact with the substrate 10. At least the portion of the second semiconductor portion 20b contacting the substrate 10 can be crystallized by inheriting the crystal structure of the substrate 10 of the foundation by solid phase epitaxy, etc. In other words, if the substrate 10 is monocrystalline, the portion of the second semiconductor portion 20b contacting the substrate 10 also may be monocrystallized.

Ideally, it is desirable for the second semiconductor portion 20b that is formed inside the substrate 10 to be monocrystallized as one body or to include the second semiconductor portion 20b in which monocrystalline is dominant. In this case, for example, the crystal structure of the entire second semiconductor portion 20b is a monocrystalline crystal structure.

However, actually, this is not limited to being monocrystallized in this way. That is, a portion that is monocrystallized and a polycrystalline portion that is substantially monocrystalline may coexist in the second semiconductor portion 20b. However, in such a case, the crystal structure of the entire second semiconductor portion 20b is a crystal structure having monocrystalline as a major structure. Here, “crystal structure having monocrystalline as a major structure” refers to, for example, 70% or more of a prescribed film thickness (e.g., about 15 nm) of the second semiconductor portion 20b being a monocrystalline region.

On the other hand, for the channel body 20 and the cover film 21 that are separated from the substrate 10, although the portions not reached by the solid phase growth from the silicon of the substrate 10 are not monocrystallized, polysilicon that is made of a structure of crystallites of about several tens of nm to about 200 nm forms due to the heating (the crystallization annealing). The polysilicon portion of the channel body 20 that is separated from the substrate 10 is referred to as the first semiconductor portion 20a. In this case, the crystal structure of the entire first semiconductor portion 20a is a polycrystalline crystal structure.

However, actually, the entire first semiconductor portion 20a is not limited to being polycrystallized. That is, a portion that is polycrystallized and a portion that is monocrystallized may coexist in the first semiconductor portion 20a. In such a case, the crystal structure of the entire first semiconductor portion 20a is a crystal structure having polycrystalline as a major structure. Here, “crystal structure having polycrystalline as a major structure” refers to, for example, 70% or more of a prescribed film thickness (e.g., about 15 nm) of the first semiconductor portion 20a being a polycrystalline region.

Also, the crystallites of the first semiconductor portion 20a form not only from the substrate 10 side but also from, for example, the side surface of the cover film 21 contacting an oxide film (the memory film 30); and the crystallites of the first semiconductor portion 20a are crystallized by inheriting the crystal structure of the cover film 21.

The size of the crystallites can be measured by using, for example, X-ray analysis, EBSD (Electron Back Scatter Diffraction Patterns), a TEM (Transmission Electron Microscope), etc.

Then, as shown in FIG. 3B, the core insulating film 50 is formed on the inner side of the channel body 20. Thereby, the columnar portion CL is formed.

Subsequently, a slit is made in the stacked body 15; and multiple sacrificial layers 61 are removed via the slit. The multiple electrode layers WL, the source-side selection gate SGS, and the drain-side selection gate SGD shown in FIG. 1 and FIG. 2 are formed in the portions where the multiple sacrificial layers 61 were removed.

Then, the interconnect layer LI is formed by forming the insulating film 72 and the conductive film 71 inside the slit. The contact units CI and Cc are formed on the interconnect layer LI and the columnar portion CL. Subsequently, the upper layer interconnects, etc., are formed; and the semiconductor memory device of the embodiment is formed.

A method may be used in which the electrode layers WL, the source-side selection gate SGS, and the drain-side selection gate SGD are formed initially instead of forming the sacrificial layers 61.

Also, the maximum diameters C1 and C2, the maximum inner diameter C3, the thickness D1, and the width D2 described above respectively correspond to the maximum diameter of the third semiconductor portion 21a, the maximum diameter of the fourth semiconductor portion 21b, the maximum inner diameter of the third semiconductor portion 21a, the thickness of the third semiconductor portion 21a, and the width of the stepped portion 20t of FIG. 3B.

In other words, when viewed from the Z-direction, the maximum diameter C1 and the maximum inner diameter C3 of the third semiconductor portion 21a are larger than the maximum diameter C2 of the fourth semiconductor portion 21b. The thickness D1 of the third semiconductor portion 21a in the Y-direction is not less than the value of the maximum diameter C2 of the fourth semiconductor portion 21b divided by 2. In the Y-direction, the width D2 of the stepped portion MHt is not less than the thickness D1 of the third semiconductor portion 21a.

Thus, according to the embodiment, the fluctuation of the portion of the channel body 20 contacting the substrate 10 can be suppressed; and the supply of a stable cell current is possible.

### Second Embodiment

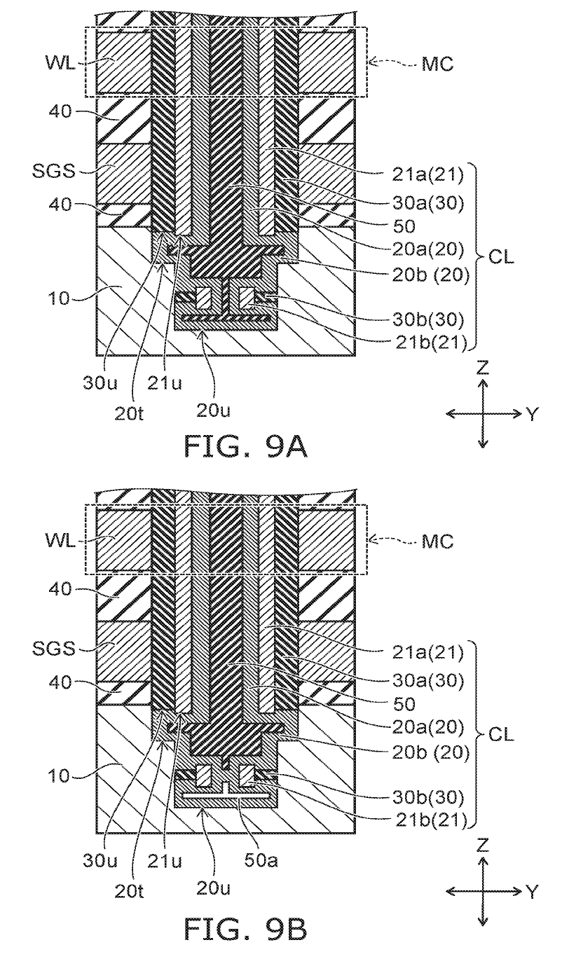

An example of the configuration of a semiconductor memory device of the embodiment will now be described with reference to FIG. 9A.

In the embodiment, the major difference from the embodiment described above is the configurations of the channel body and the cover film. Therefore, a description is partially omitted for portions similar to those of the embodiment described above.

As shown in FIG. 9A, the second insulating unit 30b and the fourth semiconductor portion 21b have hollow circular columnar configurations having the Z-direction as central axes. The fourth semiconductor portion 21b is provided on the inner side of the second insulating unit 30b.

The second semiconductor portion 20b has a lower surface 20u that is provided lower than the second insulating unit 30b. The lower surface 20u of the second semiconductor portion 20b contacts the substrate 10.

The second insulating unit 30b and the fourth semiconductor portion 21b are provided at a height between the height of the stepped portion 20t of the second semiconductor portion 20b and the height of the lower surface 20u. The second semiconductor portion 20b is provided as one body from under the stacked body 15 to the lower surface 20u via the inner side of the fourth semiconductor portion 21b.

The second semiconductor portion 20b contacts the upper surface, lower surface, and side surface of the fourth semiconductor portion 21b and contacts the upper surface and lower surface of the second insulating unit 30b.

For example, the side surface of the second insulating unit 30b is coplanar with the side surface of the second semiconductor portion 20b at or lower than the stepped portion 20t.

As shown in FIG. 9B, for example, in addition to the core insulating film 50, an air gap 50a may be provided on the inner side of the second semiconductor portion 20b. For example, the air gap 50a is provided on the inner side of the second semiconductor portion 20b provided lower than the fourth semiconductor portion 21b.

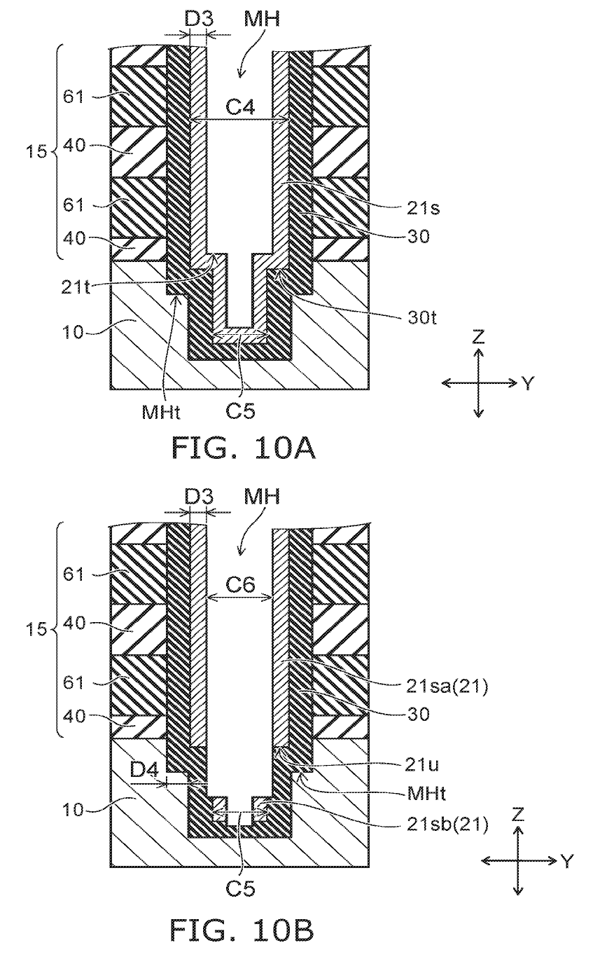

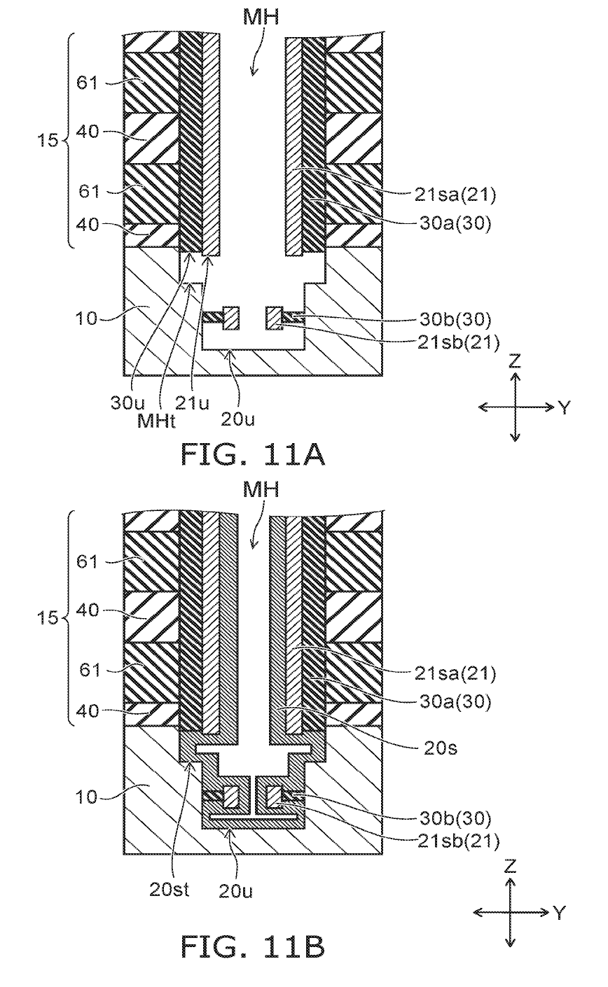

An example of a method for manufacturing the semiconductor memory device of the embodiment will now be described with reference to FIG. 10A to FIG. 11B.

In the method for manufacturing the semiconductor memory device of the embodiment, the processes up to the forming of the stepped portion MHt are similar to the processes shown in FIG. 4A to FIG. 6B; and a description is therefore omitted.

As shown in FIG. 10A, the memory film 30 is formed on the side wall of the hole MH. The memory film 30 is formed conformally inside the hole MH.

The maximum diameter of the memory film 30 higher than the stepped portion MHt is larger than the maximum diameter of the memory film 30 at or lower than the stepped portion MHt. The stepped portion 30t of the memory film 30 is formed between the height of the stepped portion MHt and the height of the surface of the substrate 10 contacting the stacked body 15.

Then, the cover film 21s is formed on the inner side of the memory film 30. The cover film 21s is, for example, a silicon-based amorphous film of amorphous silicon, etc.

When viewed from the Z-direction, a maximum diameter C4 of the cover film 21s formed to be higher than the stepped portion 30t is larger than a maximum diameter C5 of the cover film 21s formed to be at or lower than the stepped portion 30t. Also, a thickness D3 in the Y-direction of the cover film 21s formed inside the stacked body 15 is less than the value of the maximum diameter C5 divided by 2.

Thereby, a space remains inside the hole MH without the cover film 21s being filled into the inner side of the memory film 30 at or lower than the stepped portion 30t. A stepped portion 21t of the cover film 21s is formed at the height where the maximum diameter of the space inside the hole MH changes. The height of the bottom surface of the space inside the hole MH is lower than the height of the stepped portion 30t.

As shown in FIG. 10B, the side surface and lower end portion of the memory film 30 are exposed in the space inside the hole MH by causing the cover film 21s formed on the stepped portion 21t and the bottom surface of the hole MH to recede. For example, RIE using a not-shown mask is used as the method for causing the cover film 21s to recede.

Thereby, the third semiconductor portion 21sa and the fourth semiconductor portion 21sb are formed by dividing the cover film 21s vertically. For example, the third semiconductor portion 21sa and the fourth semiconductor portion 21sb have hollow circular columnar configurations having the Z-direction as central axes. The lower surface 21u of the third semiconductor portion 21sa is formed in the portion contacting the stepped portion 30t of the memory film 30.

When viewed from the Z-direction, a maximum inner diameter C6 of the third semiconductor portion 21sa is not less than the maximum diameter C5 of the fourth semiconductor portion 21sb. Also, a width D4 of the stepped portion MHt in the Y-direction is not less than the thickness D3 of the third semiconductor portion 21sa. At this time, by causing the cover film 21s to recede in the Z-direction, the side surface of the memory film 30 is exposed at the side surface of the space inside the hole MH; and the lower end portion of the memory film 30 is exposed at the bottom surface of the space inside the hole MH.

That is, when the relationship between the maximum diameter C5 and the maximum inner diameter C6 and the relationship between the thickness D3 and the width D4 described above are satisfied, the side surface of the memory film 30 can be exposed in the space inside the hole MH even in the case where the cover film 21s is not filled onto the inner side of the memory film 30 at or lower than the stepped portion 30t. Therefore, the thickness D3 of the cover film 21s can be formed to be as thin as possible; and downscaling of the device is possible. Also, the removal amount of the memory film 30 can be reduced as the device is downscaled. Therefore, the fluctuation of the removal amount of the memory film 30 can be suppressed; and the supply of a stable cell current is possible.

The side surface of the memory film 30 is exposed in the space inside the hole MH between the third semiconductor portion 21sa and the fourth semiconductor portion 21sb.

Subsequently, as shown in FIG. 11A, the side surface and lower end portion side of the memory film 30 that are exposed in the space inside the hole MH are removed. Thereby, the substrate 10 that includes the stepped portion MHt is exposed at the bottom surface and side surface of the space inside the hole MH. At this time, the first insulating unit 30a and the second insulating unit 30b are formed by dividing the memory film 30 vertically.

The lower surface 30u of the first insulating unit 30a is formed at a height between the height of the surface of the substrate 10 contacting the stacked body 15 and the height of the lower surface 21u of the third semiconductor portion 21sa. The lower surface 21u of the third semiconductor portion 21sa is formed at a height between the height of the lower surface 30u of the first insulating unit 30a and the height of the stepped portion MHt. Thereby, similarly to the embodiment described above, the supply of a stable cell current is possible.

The second insulating unit 30b and the fourth semiconductor portion 21sb are exposed in the space inside the hole MH. The second insulating unit 30b and the fourth semiconductor portion 21sb are separated from the bottom surface of the hole MH.

The second insulating unit 30b contacts the side wall (the substrate 10) of the hole MH and is surrounded with the side wall (the substrate 10) of the hole MH. Also, the fourth semiconductor portion 21sb contacts the second insulating unit 30b and is surrounded with the second insulating unit 30b. At this time, the fourth semiconductor portion 21sb is fixed by the second insulating unit 30b; the second insulating unit 30b is fixed by the substrate 10; and the fourth semiconductor portion 21sb and the second insulating unit 30b that become dust can be suppressed. Therefore, it is possible to increase the yield of the device.

Similarly to the embodiment described above, for example, isotropic etching is used as the method for removing the memory film 30. Other than the description recited above, for example, wet etching may be used.

As shown in FIG. 11B, the channel body 20s is formed as one body inside the hole MH. The channel body 20s contacts the side surface and bottom surface of the substrate 10 exposed at the hole MH side wall and includes the stepped portion 20st.

At a position that is higher than the stepped portion 20st, the channel body 20s contacts the lower surface 30u of the first insulating unit 30a and the side surface and lower surface 20u of the third semiconductor portion 21sa.

At a position that is lower than the stepped portion 20st, the channel body 20s contacts the upper surface, lower surface, and side surface of the fourth semiconductor portion 21sb. The channel body 20s contacts the upper surface and lower surface of the second insulating unit 30b. The channel body 20s has the lower surface 20u that is formed to be lower than the second insulating unit 30b and the fourth semiconductor portion 21sb. The lower surface of the channel body 20s contacts the substrate 10.

Subsequently, similarly to the embodiment described above, heating of the channel body 20s and the cover film 21s is performed. Thereby, the channel body 20 and the cover film 21 that are crystallized are formed.

Then, as shown in FIG. 9A, the core insulating film 50 is formed on the inner side of the channel body 20. Thereby, the columnar portion CL is formed. At this time, as shown in FIG. 9B, for example, the air gap 50a may be formed by the channel body 20 being plugged on the inner side of the fourth semiconductor portion 21b.

Subsequently, a slit is made in the stacked body 15; and the multiple sacrificial layers 61 are removed via the slit. The multiple electrode layers WL, the source-side selection gate SGS, and the drain-side selection gate SGD shown in FIG. 1 and FIG. 2 are formed in the portions where the multiple sacrificial layers 61 were removed.

Then, the interconnect layer LI is formed by forming the insulating film 72 and the conductive film 71 inside the slit. The contact units CI and Cc are formed on the interconnect layer LI and the columnar portion CL. Subsequently, the upper layer interconnects, etc., are formed; and the semiconductor memory device of the embodiment is formed.

A method may be used in which the electrode layers WL, the source-side selection gate SGS, and the drain-side selection gate SGD are formed initially instead of forming the sacrificial layers 61.

Also, the maximum diameters C4 and C5, the maximum inner diameter C6, the thickness D3, and the width D4 described above respectively correspond to the maximum diameter of the third semiconductor portion 21a, the maximum diameter of the fourth semiconductor portion 21b, the maximum inner diameter of the third semiconductor portion 21a, the thickness of the third semiconductor portion 21a, and the thickness of the stepped portion 20t of FIG. 9A.

In other words, when viewed from the Z-direction, the maximum diameter C4 and the maximum inner diameter C6 of the third semiconductor portion 21a are larger than the maximum diameter C5 of the fourth semiconductor portion 21b. The thickness D3 of the third semiconductor portion 21a in the Y-direction is less than the value of the maximum diameter C5 of the fourth semiconductor portion 21b divided by 2. In the Y-direction, the width D4 of the stepped portion MHt is not less than the thickness D3 of the third semiconductor portion 21a.

Thus, according to the embodiment, similarly to the embodiment described above, the fluctuation of the portion of the channel body 20 contacting the substrate 10 can be suppressed; and the supply of a stable cell current is possible.

Also, similarly to the embodiment described above, the stepped portion MHt is formed. Thereby, the process of removing the memory film 30 from the side surface can be implemented easily.

Also, the precision in the Z-direction when forming the stepped portion MHt is higher than the precision in the Z-direction when the hole MH is made to pierce the stacked body 15 and reach the substrate 10. Thereby, the position of the side surface of the memory film 30 exposed in the hole MH can be suppressed with high precision; and the supply of a stable cell current is possible.

Further, by forming the stepped portion MHt, a portion of the damaged portion 10d formed in the substrate 10 surface can be removed when making the hole MH. Thereby, the supply of a stable cell current is possible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device, comprising:
a substrate;
a stacked body provided on the substrate, the stacked body including a plurality of electrode layers stacked with an insulating layer interposed;
a first semiconductor film provided as one body inside the stacked body and inside the substrate, the first semiconductor film including
a first semiconductor portion provided inside the stacked body, the first semiconductor portion extending in a stacking direction of the stacked body, and
a second semiconductor portion provided inside the substrate and being in contact with the substrate;
a first insulating film provided inside the stacked body and inside the substrate, the first insulating film including a charge storage film, the first insulating film including
a first insulating unit provided between the first semiconductor portion and the plurality of electrode layers, the first insulating unit extending in the stacking direction and having a lower surface contacting the second semiconductor portion, and
a second insulating unit provided inside the substrate, the second insulating unit being separated from the first insulating unit with the second semiconductor portion interposed, the second insulating unit contacting the substrate and the second semiconductor portion;
a second semiconductor film provided inside the stacked body and inside the substrate, the second semiconductor film including
a third semiconductor portion provided between the first semiconductor portion and the first insulating unit, the third semiconductor portion extending in the stacking direction and having a lower surface lower than a height of the lower surface of the first insulating unit, and
a fourth semiconductor portion provided inside the substrate, separated from the third semiconductor portion and the substrate, and provided between the second semiconductor portion and the second insulating unit.

2. The semiconductor memory device according to claim 1, wherein the second semiconductor portion includes a stepped portion provided at a height between the height of the lower surface of the first insulating unit and a height of a surface of the second semiconductor portion contacting the second insulating unit.

3. The semiconductor memory device according to claim 2, wherein the stepped portion and the lower surface of the first insulating unit overlap as viewed from the stacking direction.

4. The semiconductor memory device according to claim 2, wherein the lower surface of the third semiconductor portion is provided at a height between the height of the lower surface of the first insulating unit and the height of the stepped portion.

5. The semiconductor memory device according to claim 2, wherein a width of the stepped portion of the second semiconductor portion is not less than a thickness of the third semiconductor portion in a first direction intersecting the stacking direction.

6. The semiconductor memory device according to claim 1, wherein a maximum inner diameter of the third semiconductor portion is larger than a maximum diameter of the fourth semiconductor portion as viewed from the stacking direction.

7. The semiconductor memory device according to claim 1, wherein the lower surface of the first insulating unit is provided at a height between a height of a surface of the substrate contacting the stacked body and the height of the lower surface of the third semiconductor portion.

8. The semiconductor memory device according to claim 1, wherein the fourth semiconductor portion is surrounded with the second insulating unit.

9. The semiconductor memory device according to claim 1, wherein the fourth semiconductor portion is surrounded with the second semiconductor portion.

10. The semiconductor memory device according to claim 1, wherein a thickness of the third semiconductor portion in a first direction intersecting the stacking direction is not less than the value of the maximum diameter of the fourth semiconductor portion as viewed from the stacking direction divided by 2.

11. The semiconductor memory device according to claim 1, wherein the second insulating unit contacts a lower surface of the second semiconductor portion.

12. The semiconductor memory device according to claim 1, wherein a thickness of the third semiconductor portion in a first direction intersecting the stacking direction is less than the value of a maximum diameter of the fourth semiconductor portion as viewed from the stacking direction divided by 2.

13. The semiconductor memory device according to claim 1, wherein the second semiconductor film has a lower surface provided lower than the second insulating unit.

14. The semiconductor memory device according to claim 1, wherein the fourth semiconductor portion has a hollow circular columnar configuration, and the second semiconductor portion is provided on an inner side of the fourth semiconductor portion.

15. The semiconductor memory device according to claim 1, wherein the second semiconductor portion contacts an upper surface, a lower surface, and a side surface of the fourth semiconductor portion.

16. The semiconductor memory device according to claim 1, wherein the second semiconductor portion contacts an upper surface and a lower surface of the second insulating unit.

17. The semiconductor memory device according to claim 1, further comprising an air gap provided on an inner side of the second semiconductor portion.

18. A method for manufacturing a semiconductor memory device, comprising:
forming a stacked body on a substrate, the stacked body including a plurality of first layers stacked with an insulating layer interposed;
making a hole piercing the stacked body and reaching the substrate;
causing a side surface of the stacked body exposed at a side surface of the hole to recede;
forming a stepped portion of the substrate inside the hole by causing a bottom portion of the hole to recede;
forming a first insulating film on an inner wall of the hole including the stepped portion, the first insulating film including a charge storage film;
forming a second semiconductor film on an inner side of the first insulating film;
exposing the first insulating film in a space inside the hole by removing a portion of the second semiconductor film;
exposing the stepped portion in the space inside the hole by removing the first insulating film exposed in the space inside the hole; and
forming a first semiconductor film as one body on the stepped portion and on an inner side of the second semiconductor film.

19. The method for manufacturing the semiconductor memory device according to claim 18, wherein the exposing of the first insulating film in the space inside the hole includes dividing the second semiconductor film and includes causing the second semiconductor film formed between a height of the stepped portion and a height of a lower surface of the first insulating film to remain.

20. The method for manufacturing the semiconductor memory device according to claim 19, wherein the exposing of the first insulating film in the space inside the hole includes removing a lower surface of the second semiconductor film.
